(19) United States
(12) Patent Application Publication
(10) Pub. No.: US 2009/0091963 A1
(43) Pub. Date: Apr. 9, 2009

(54) MEMORY DEVICE

(75) Inventor: Shwetal A. Patel, San Jose, CA (US)

Correspondence Address: LARSON NEWMAN ABEL & POLANSKY, LLP, 5914 WEST COURTYARD DRIVE, SUITE 200, AUSTIN, TX, 78730, US

(73) Assignee: ADVANCED MICRO DEVICES, INC., Sunnyvale, CA (US)

(21) Appl. No.: 11/867,208

(22) Filed: Oct. 4, 2007

(51) Int. Cl. G11C 5/06

(52) U.S. Cl. 365/63

(57) ABSTRACT

A first DRAM device comprises a first input connected to a first trace line to receive an address signal and a second input is connected to receive an operating voltage, such as Vdd. A second DRAM device comprises a first input connected to the first trace line to receive the address signal and a second input to receive the operating voltage. A first signal termination structure is connected to the first trace line, wherein the first signal termination structure is to terminate the first trace line to the operating voltage.

### FIELD OF THE DISCLOSURE

The present disclosure relates to electronic devices, and more particularly to electronic device having dynamic random access memories.

### DESCRIPTION OF THE RELATED ART

A dual In-Line Memory Modules (DIMMs) that supports DDR Dynamic Random Access Memories (DRAMs) is connected to an address bus, a command bus, and a control bus each of which are terminated at a reference voltage Vtt that is typically set to one-half an operating voltage Vdd of the DRAMS. This voltage termination results in DIMMs that consume power when their busses are sitting idle at Vdd or Vss. The power consumption can vary depending upon the size of the busses terminated at Vtt as well as by the on-resistance of any termination resistors used to generate Vtt. Therefore, a device and method of reducing the power consumption of a device comprising a DRAM module would be useful.

### BRIEF DESCRIPTION OF THE DRAWINGS

The present disclosure may be better understood, and its numerous features and advantages made apparent to those skilled in the art by referencing the accompanying drawings.

FIG. 1 illustrates a block diagram of a device in accordance with a specific embodiment of the present disclosure;

FIG. 2 illustrates a block diagram of a specific embodiment of various busses illustrated at FIG. 1;

FIG. 3 illustrates a block diagram of a specific embodiment of a termination structure illustrated at FIG. 2;

FIG. 4 illustrates a block diagram of a specific embodiment of a termination structure illustrated at FIG. 2;

FIG. 5 illustrates a flow diagram of a specific embodiment of the present disclosure;

FIG. 6 illustrates a block diagram of a device in accordance with a specific embodiment of the present disclosure;

FIG. 7 illustrates a flow diagram of a specific embodiment of the present disclosure;

FIG. 8 illustrates a block diagram of a device in accordance with a specific embodiment of the present disclosure;

FIG. 9 illustrates a block diagram of a device in accordance with a specific embodiment of the present disclosure; and

FIG. 10 illustrates a block diagram of a device in accordance with a specific embodiment of the present disclosure.

### DETAILED DESCRIPTION

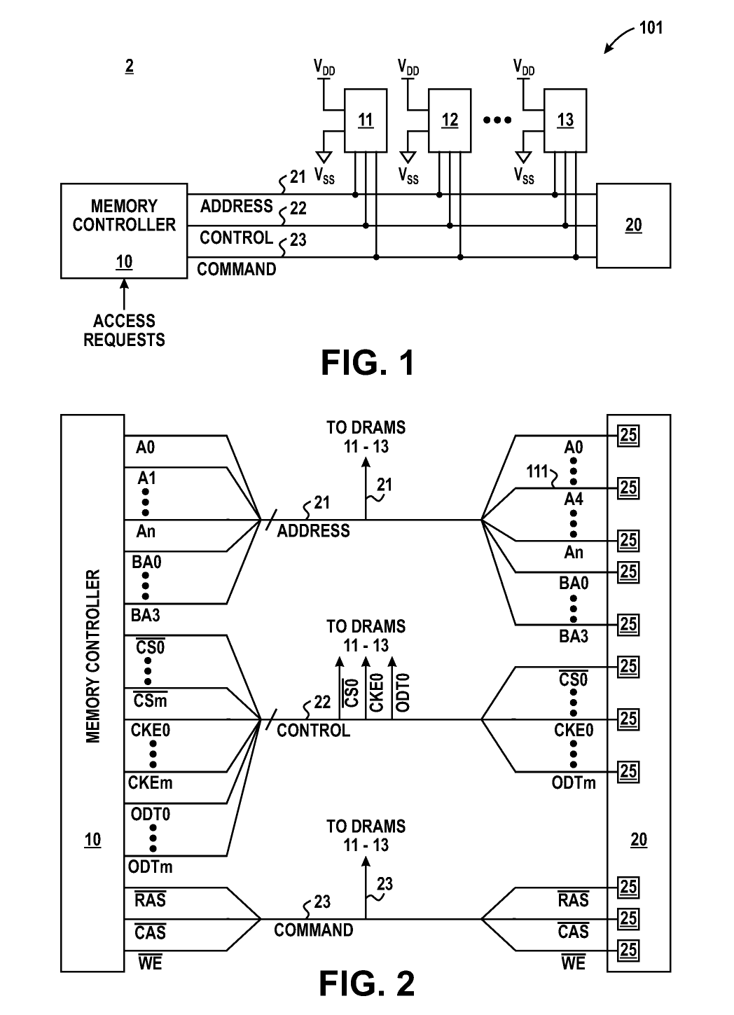

In accordance with a specific embodiment of the present disclosure an address bus, a control bus, and a command bus of a memory system are terminated at a termination voltage that is equal to one of two operating voltages, Vdd or Vss. By driving the busses to the same operating voltage used as Vtt, power consumption when the bus is idle can be reduced. The present disclosure will be better understood with reference to FIGS. 1-10.

FIG. 1 illustrates a device 2 comprising a memory system. Device 2 can be a laptop computer, a desktop computer, a server, a specific application, such as a set-top box, and the like. A portion 101 of the memory system of device 2 is illustrated at FIG. 1 that includes a plurality of DRAM devices 11-13, a termination device 20, a memory controller 10, address bus 21, control bus 22, command bus 23, a Vdd voltage reference bus, labeled Vdd, a Vss voltage reference bus, labeled Vss, and termination module 20.

Each DRAM device 11-13 includes a terminal connected to the Vss voltage reference bus to receive an operational voltage Vss during operation, and a terminal connected to the Vdd voltage reference bus to receive an operation voltage Vdd during operation. The address bus 21 and the command bus 23 are connected to each of the DRAM devices 11-13, to the termination module 20, and to the memory controller 10. In addition, one set of control bit lines from control bus 23, which includes one chip select from the control bus 23, is provided to each of the DRAM devices 11-13 to select the DRAM devices 11-13 as a group of DRAM devices to be accesses simultaneously by a common set of bus signals.

FIG. 2 illustrates a more detailed view of the trace lines, also referred to as lines that form the address bus 21, control bus 22, command bus 23, and termination module 20. In the specific embodiment illustrated, address bus 21 includes a plurality of address bit lines A0-An and bank address bit lines BA0-BA3, where n represents an integer number. Each bit line of the address bus is connected to corresponding input terminals at each of the DRAM devices 1′-13. For example, bit line A0 is connected to an input terminal A0 at each of the DRAM devices 1′-13.

Control bus 22 includes a plurality of control bit lines including chip select bit lines C̅S̅0̅- C̅S̅m̅, clock enable bit lines CKE0-CKEm, and on-die termination bit lines IDT0-IDTm, where m represents an integer. One set of control bit lines, such as C̅S̅0̅, CKE0, and ODT0, is provided to DRAM devices 11-13. Therefore, each bit line of the set of control bit lines is connected to corresponding input terminals at each of the DRAM devices 11-13.

Command bus 23 includes a plurality of command bit lines including R̅A̅S̅, C̅A̅S̅, and W̅E̅. Each bit line of the command bus 23 is connected to corresponding input terminals at each of the DRAM devices.

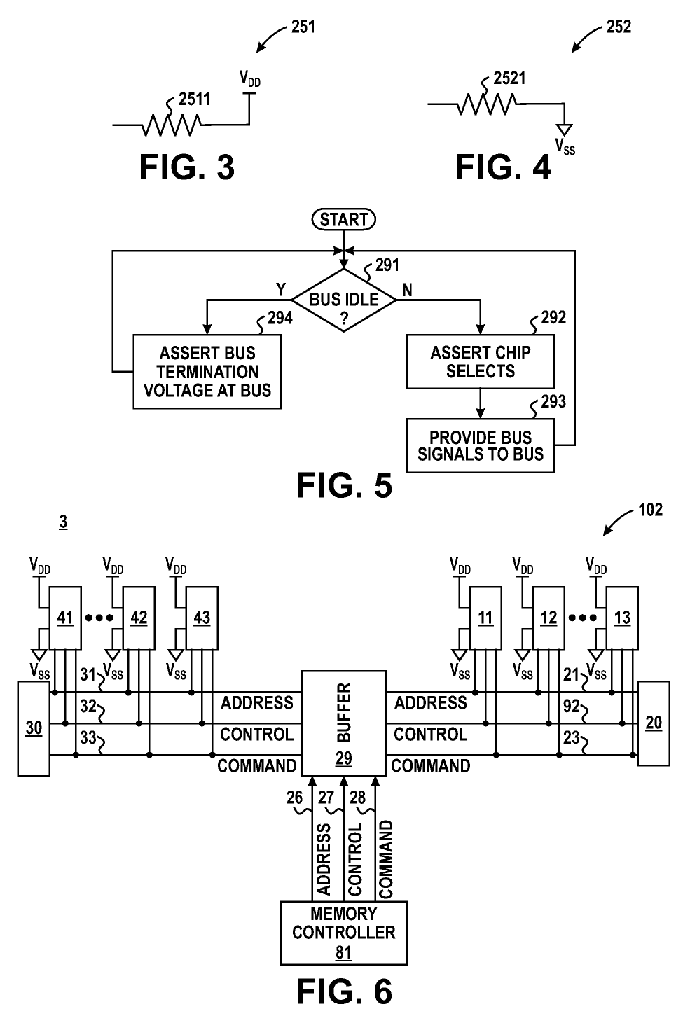

Each bit line of the address bus 21, the control bus 22, and the command bus 23 are terminated at corresponding termination structures 25 of the termination module 20. FIG. 3 illustrates a termination structure 251 that can represent one embodiment of termination structure 25. Termination structure 251 includes a resistive element 2511 having a first terminal that is connected to its respective bit line, and a second terminal that is connected to a voltage reference bus that provides the operational voltage Vdd.

FIG. 4 illustrates a termination structure 252 that can represent one embodiment of termination structure 25. Termination structure 252 includes a resistive element 2521 having a first terminal that is connected to its respective bit line, and a second terminal that is connected to a voltage reference bus that provides the operational voltage Vss.

A specific mode of operation for memory controller 10 is represented by the flow diagram of FIG. 5. At block 291 it is determined by the memory controller 10 whether the address bus 21, control bus 22, and command bus 23 are to be placed in an idle state. This is determined based upon whether there are any pending access requests at memory controller 10 for memory devices connected to these busses. If there are no pending access requests, it is determined that the bus is to be idle and flow proceeds to block 294 where the memory controller 10 provides the termination voltage, Vdd or Vss, to each bit line of the bus. In response to providing the termination voltage to each bit line of the bus there is no longer a voltage differential along the individual bit lines thereby reducing the amount of current flowing along individual bit lines between a source device, such as the memory controller 10, and the termination structure 25, thereby reducing power consumption.

If there are pending requests for the DRAM devices 11-13 the memory controller 10 will determine that the bus is not to be idle, but instead that the bus is to access DRAM devices 11-13, and flow proceeds to block 292. At block 292 memory controller 10 provides control information by asserting the chip select information connected to DRAM devices 11-13, at a block 293 the memory controller 10 asserts address and command information at the address bus 21 and the control bus 22.

FIG. 6 illustrates a device 3 comprising a memory system. Device 3 can be a laptop computer, a desktop computer, a server, a specific application, such as a set-top box, and the like. A portion 102 of the memory system of device 3 is illustrated at FIG. 6 that includes: a plurality of DRAM devices 11-13 and 41-43; termination devices 20 and 30; a memory controller 81; address busses 21, 31, and 26; control busses 32, 27, and 92; and command busses 23, 33, and 28.

Elements of FIG. 6 having identical numbering to elements of FIG. 1 are similar to those elements previously described with reference previous figures. Address bus 26, control bus 27, and command bus 28 are each connected to the memory controller 81 and to a set of inputs at buffer 29. Address bus 21, control bus 92, and command bus 23 are connected to a first set of outputs at buffer 29. Address bus 31, control bus 32, and command bus 33 are connected to termination module 30 and to a second set of outputs at buffer 29.

Buffer 29 receives bus signals from memory controller 81, and provides the bus signals to different sets of DRAM devices after buffering. The buffering performed by buffer 29 can be synchronous or combinational. Synchronous buffering uses a clock signal to latch the bus signals from memory controller 81 prior to being provided to multiple output terminals. Combinational buffering does not latch the bus signals prior to providing the bus signal to multiple output buffers.

In one embodiment, the memory controller 81 operates similar to memory controller 10, as previously described, and provides to the address bus 26, control bus 27, and command bus 28 either the bus signals necessary to access DRAM devices 11-13 or the termination voltage needed to place the busses connected to the DRAM devices at the termination voltage during an idle mode. In response, the buffer 29 will provide one set of buffered bus signals based on the signals received from the memory controller 81 to the address bus 21, the control bus 92, and the command bus 23, and another set of buffered bus signals, identical to the first set of buffered bus signals to the address bus 31, the control bus 32, and the command bus 33. Note that DRAMs 41-43 and 11-13 are accessed simultaneously using the same bus signals and that the buffer 29 is connected to the control bus 27 receive only one set of control signals from control bus 27, such as CS0, CKE0, and ODT0, which is buffered and provided to control bus 32 and control bus 92.

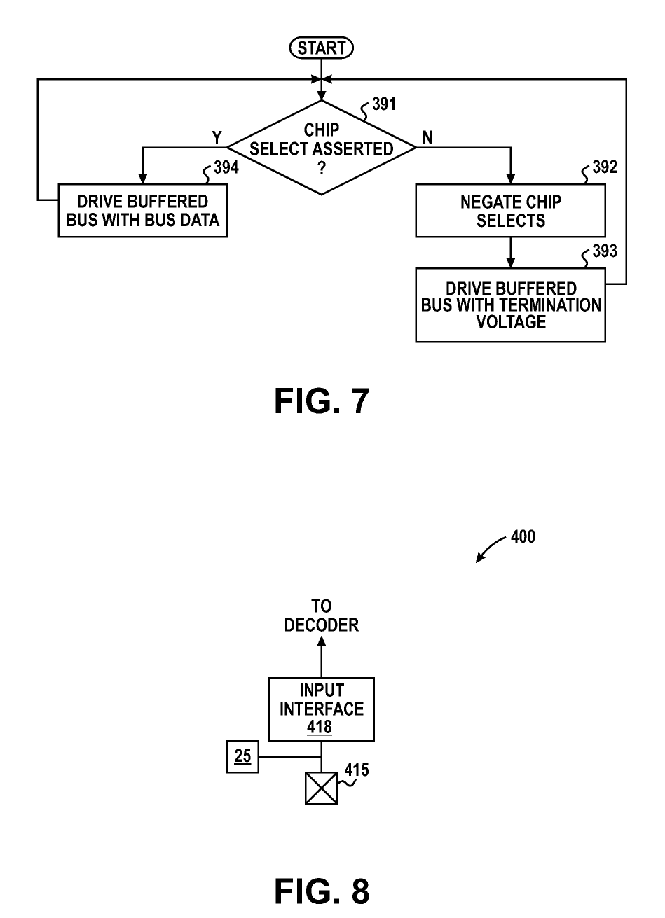

In an alternate embodiment, the memory controller 81 can select between multiple sets of memory by asserting one set of control signals at a time. In response to accessing data from a different set of DRAMs, the memory controller 81 will negate the chip select provided to buffer 29 for DRAM devices 11-13. In response, the buffer 29 can operate as indicated at the flow diagram of FIG. 7, where at block 391 the buffer 29 determines whether its received chip select signal is asserted. If so, flow proceeds to block 394. Otherwise, flow proceeds to block 392, where the buffer 29 provides the negated chip select signal to the DRAM devices and at block 393 provides the termination voltage to the address busses 21 and 31, the control busses 32 and 92, and the command busses 23 and 33.

At block 394, in response to determining the chip select signal received at buffer 29 is enabled, the buffer 29 will provide the ADDRESS signals received at the address bus 26, the CONTROL signals received at the control bus 27, and the COMMAND signals received at the command bus 28 to its buffered outputs. The flow from block 394 and block 393 returns to block 391.

FIG. 8 illustrates a portion of an integrated circuit device 400. In one embodiment the integrated circuit device 400 is a DRAM device. In an alternate embodiment the integrated circuit device 400 is a buffer, such as buffer 29 described herein. The illustrated portion of the integrated circuit device 400 at FIG. 8 includes bond pad 415 to receive a signal from a bit line, such as from an address bit line, an input interface module 418 that can condition signals received at input pad 415 prior to providing them to a decoder, and a termination structure 25 connected to a voltage reference bus as previously described. During operation, the termination voltage is provided to bond pad 415 when the bus to which it is connected is idle. Since the received voltage is the same as the termination voltage at termination structure 25, the amount of power dissipated by current passing through the bond pad 415 is reduced. In one embodiment, the termination structure 25 can receive a ODT signal to enable termination.

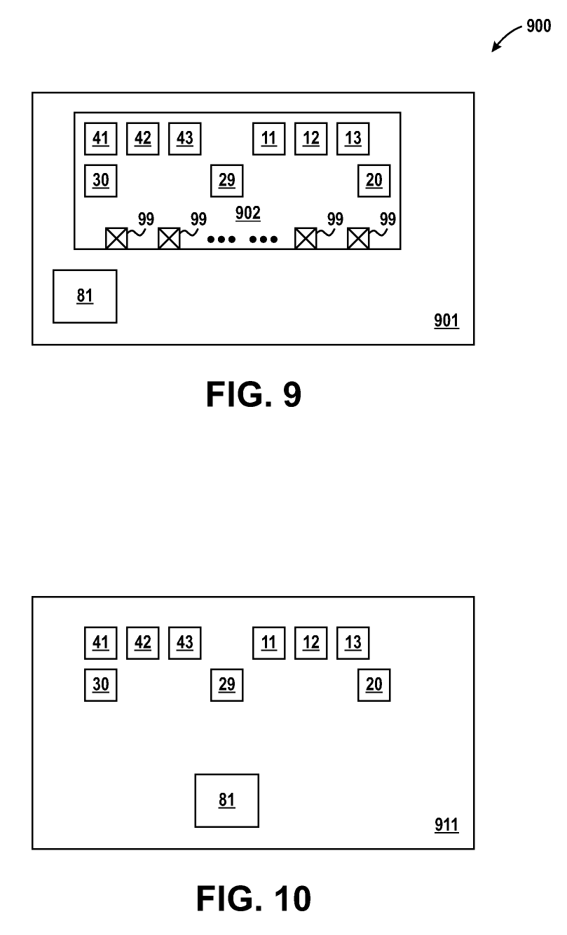

FIG. 9 illustrates a block diagram of a device 900 such as a computer. In this embodiment, the device 900 includes a motherboard 901, i.e., a printed circuit board, having a portion of a memory system disposed thereon, e.g., devices solder attached, and a dual in-line memory module (DIMM) printed circuit board 902 having a portion of the memory system disposed thereon. By way of example, the elements of FIG. 6 are shown to be disposed on either the motherboard 901 or the DIMM printed circuit board 902. Therefore, a DIMM includes the DIMM printed circuit board 902, DRAM devices 41-43, 11-13, buffer 29, and termination modules 30 and 20. In addition, the DIMM includes DIMM connectors 99 that provide an interface between DIMM devices and a socket at motherboard 901. The memory controller 81 is disposed on the motherboard 901, and like any of the described devices, can be integrated as part of a larger device.

FIG. 10 illustrates an alternate embodiment where the memory system is entirely disposed on a common printed circuit board 911. Therefore, the DRAM devices 41-43, 11-13, buffer 29, termination modules 30 and 20, and the memory controller 81 are formed on a common printed circuit board 911.

In the preceding detailed description, reference has been made to the accompanying drawings that form a part hereof, and in which are shown by way of illustration specific embodiments in which the invention may be practiced. These embodiments and certain variants thereof, have been described in sufficient detail to enable those skilled in the art to practice the invention. It is to be understood that other suitable embodiments may be without departing from the spirit or scope of the invention. In addition, it will be appreciated that the functional blocks shown in the figures could be further combined or divided in a number of manners without departing from the spirit or scope of the invention. The preceding detailed description is, therefore, not intended to be limited to the specific forms set forth herein, but on the contrary, it is intended to cover such alternatives, modifications, and equivalents, as can be reasonably included within the spirit and scope of the appended claims.

1. A device comprising:
a first dynamic random access memory (DRAM) comprising a first terminal to receive an address signal, and a second terminal to receive an operating voltage;
a second dynamic random access memory (DRAM) comprising a first terminal to receive the address signal, and a second terminal to receive the operating voltage;
a first trace line connected to the first terminal of the first DRAM, and to the first terminal of the second DRAM;
a first signal termination structure comprising a first terminal connected to the first trace line, and a second terminal; and
a voltage reference bus connected to the second terminal of the first DRAM, to the second terminal of the first DRAM, and to the second terminal of the signal termination structure.

2. The device of claim 1 further comprising:
a printed circuit board having the first DRAM, second DRAM, first trace line, second termination structure, and voltage reference bus disposed thereupon, and further comprising a DIMM connector connected to the first trace line.

3. The device of claim 1 wherein the second terminal of the first DRAM is to receive a Vss operating voltage.

4. The device of claim 1 wherein the second terminal of the first DRAM is to receive a Vdd operating voltage.

5. The device of claim 1 further comprising:
a buffer module comprising a first terminal to receive a signal, and a second terminal connected to the first trace line to provide a buffered representation of the signal.

6. The device of claim 5 further comprising:
a printed circuit board having the first DRAM, second DRAM, first trace line, second termination structure, voltage reference bus, and the buffer disposed thereupon, and further comprising a DIMM connector; and
a second trace line connected to the edge connector, and to the input of the synchronous buffer.

7. The device of claim 5 wherein the buffer module further comprises:
a chip select terminal to receive a chip select signal; and
the second terminal is to provide the buffered representation of the signal in response to the chip select terminal receiving an asserted signal, and the second terminal is to provide a signal having the same voltage as the voltage reference bus in response to the chip select terminal receiving a negated signal.

8. The device of claim 1 wherein:
the first DRAM further comprises a third terminal to receive a control signal;
the second DRAM further comprises a third terminal to receive the control signal;
a second trace line connected to the third terminal of the first DRAM, and to the third terminal of the second DRAM; and
a second signal termination structure comprising a first terminal connected to the second trace line, and a second terminal connected to the voltage reference bus.

9. The device of claim 8 wherein:
the first DRAM further comprises a fourth terminal to receive a command signal;
the second DRAM further comprises a fourth terminal to receive the command signal;
a third trace line connected to the fourth terminal of the first DRAM, and to the fourth terminal of the second DRAM; and
a third signal termination structure comprising a first terminal connected to the third trace line, and a second terminal connected to the voltage reference bus.

10. The device of claim 1 further comprising:
a memory controller comprising an address generation module having a first terminal coupled to the first trace line to provide the address signal in response to the memory controller determining data at the first and second DRAM is being accessed, and to provide the operating voltage in response to the memory controller determining the first and second DRAM are in an idle state.
